(19) United States
(12) Patent Application Publication
(10) Pub. No.: US 2007/0059879 A1
(43) Pub. Date: Mar. 15, 2007

(54) Pixel structure and fabricating method thereof

(76) Inventor: Chin-Kuo Ting, Gueishan Township (TW)

Correspondence Address: J.C. Patents, Inc., Suite 250, 4 Venture, Irvine, CA, 92618, US

(21) Appl. No.: 11/403,425

(22) Filed: Apr. 12, 2006

(30) Foreign Application Priority Data
Sep. 14, 2005 (TW) 94131597

(51) Int. Cl. H01L 21/8242

(52) U.S. Cl. 438/239; 257/296

(57) ABSTRACT

A pixel structure is provided, which includes a substrate, a thin film transistor (TFT), a capacitor, a protection layer and a pixel electrode. The substrate has an active device region and a capacitor region and a plurality of openings are formed within the capacitor region. Besides, the TFT is disposed within the active device region, while the capacitor is disposed within the capacitor region and formed on the openings. The protection layer covers the TFT and the capacitor. The pixel electrode is disposed on the protection layer and electrically connected to the TFT and the capacitor.

### CROSS-REFERENCE TO RELATED APPLICATION

This application claims the priority benefit of Taiwan application serial no. 94131597, filed on Sep. 14, 2005. All disclosure of the Taiwan application is incorporated herein by reference.

### BACKGROUND OF THE INVENTION

1. Field of Invention

The present invention relates to a pixel structure and a fabricating method thereof, and particularly to a pixel structure having high aperture ratio and a fabricating method thereof.

2. Description of the Related Art

A thin film transistor (TFT) liquid crystal display (LCD) is normally formed by a TFT array substrate, an counter substrate and a liquid crystal layer disposed between the two substrates. The TFT array substrate mainly includes a substrate, pixel structures arranged in an array on the substrate, scanning lines and data lines. The above-mentioned pixel structure is mainly formed by a TFT, a pixel electrode and a storage capacitor Cst. The signals are delivered by a scanning line and a data line to the corresponding pixel structure for display. The pixel structure can maintain the display function with the assistance of the storage capacitor.

FIG. 1 is a schematic top view of a conventional pixel structure, and FIG. 2 is a schematic cross-sectional view along plane A-A′ of the conventional pixel structure in FIG. 1. Referring to FIGS. 1 and 2, the conventional pixel structure 100 includes a substrate 110, a TFT 120, a pixel electrode 130 and a storage capacitor 140. The conventional pixel structure 100 is driven by a scanning line 10 and a data line 20. The TFT is disposed on the substrate 110 and includes a gate 120g, a source 120s, a drain 120d, a semiconductor layer 120c, a gate insulation layer 120i and a protection layer 122.

The storage capacitor 140 includes a lower electrode layer 142 and an upper electrode layer 144, wherein the lower electrode layer 142 is disposed on the substrate 110, while the above-mentioned gate insulation layer 120i covering the gate 120g and the lower electrode layer 142 is disposed between the lower electrode layer 142 and the upper electrode layer 144. Besides, the protection layer 122 covers the source 120s, the drain 120d, the semiconductor layer 120c and the upper electrode layer 144. The upper electrode layer 144 is electrically connected to the pixel electrode 130 through a via hole W1 formed in the protection layer 122, while the upper electrode layer 144 and the drain 120d are formed as the same layer and electrically connected to each other.

Note that the storage capacitor 140 occupies a part of the pixel structure 100 and the lower electrode layer 142 and the upper electrode layer 144 thereof are made of metal. Therefore, the lower electrode layer 142 and the upper electrode layer 144 would block the light transmittance. In other words, the larger the area occupied by the storage capacitor 140 within the region of the pixel structure 100, the lower the aperture ratio of the display region, which reduces the display quality of the TFT LCD.

### SUMMARY OF THE INVENTION

An object of the present invention is to provide a pixel structure, suitable for reducing the area on the substrate occupied by a storage capacitor without affecting the predetermined capacitance.

Another object of the present invention is to provide a method for fabricating the pixel structure, suitable for fabricating a storage capacitor with a specific structure to increase the aperture ratio of the display region.

The present invention provides a method for fabricating a pixel structure. First, a substrate having an active device region and a capacitor region is provided. Next, a plurality of openings are formed within the capacitor region of the substrate. A gate is formed within the active device region and a first electrode layer is formed within the capacitor region, wherein the first electrode layer is formed on the openings. Further, a gate insulation layer is formed on the substrate and covers the gate and the first electrode layer. A semiconductor layer is formed on the gate insulation layer over the gate. Thereafter, a source and a drain are formed on the semiconductor layer, and a second electrode layer is formed within the capacitor region and covers the gate insulation layer. After that, a protection layer is formed over the substrate and covers the source, the drain and the second electrode layer. A pixel electrode is formed on the protection layer and is electrically connected to the drain and the second electrode layer, respectively.

According to an embodiment of the present invention, the method for forming the openings includes forming a patterned mask layer; conducting an etching process to form the openings; and removing the patterned mask layer.

According to an embodiment of the present invention, the material of the patterned mask layer includes photoresist.

According to an embodiment of the present invention, the material of the patterned mask layer includes silicon nitride (SiNx).

According to an embodiment of the present invention, the etching process includes a dry etching process.

According to an embodiment of the present invention, the method for removing the patterned mask layer includes a wet etching process.

According to an embodiment of the present invention, the radius of each opening is about 0.5˜3 μm.

According to an embodiment of the present invention, the depth of each opening is about 5˜10 μm.

According to an embodiment of the present invention, the method for forming the protection layer includes a spin on glass (SOG) process.

According to an embodiment of the present invention, prior to forming the pixel electrode on the protection layer, the method further includes forming a via hole in the protection layer and the via hole exposes the drain and the second electrode layer.

According to an embodiment of the present invention, the formed second electrode layer is connected to the drain.

According to an embodiment of the present invention, prior to forming the pixel electrode on the protection layer, the method further includes forming a via hole in the protection layer and the via hole exposes the second electrode layer.

According to an embodiment of the present invention, the method for forming the gate and the first electrode layer includes the following steps. First, a deposition process is conducted to form a metal layer and the deposition process is selected from a group consisting of an organic metal chemical vapor deposition (organic metal CVD) process, a molecule layer epitaxy process and an atom layer chemical vapor deposition (atom layer CVD) process. Then, a lithography process and an etching process are conducted for patterning the metal layer.

According to an embodiment of the present invention, the method for forming the source, the drain and the second electrode layer includes the following steps. First, a deposition process is conducted to form a metal layer and the deposition process is selected from a group consisting of an organic metal chemical vapor deposition (organic metal CVD) process, a molecule layer epitaxy process and an atom layer chemical vapor deposition (atom layer CVD) process. Then, a lithography process and an etching process are conducted for patterning the metal layer.

The present invention further provides a pixel structure, which includes a substrate, a thin film transistor (TFT), a capacitor, a protection layer and a pixel electrode. The substrate has an active device region and a capacitor region, and a plurality of openings are formed within the capacitor region of the substrate. Besides, the TFT is disposed within the active device region and a capacitor is formed within the capacitor region, wherein the capacitor formed on the surface of the openings. The protection layer covers the TFT and the capacitor. The pixel electrode is disposed on the protection layer and is electrically connected to the TFT and the capacitor, respectively.

According to the pixel structure provided by an embodiment of the present invention, the radius of each opening is, for example, about 0.5˜3 μm.

According to the pixel structure provided by an embodiment of the present invention, the depth of each opening is, for example, about 5˜10 μm.

In the pixel structure of the present invention, a plurality of openings are formed in the substrate and a capacitor is formed on the surface of the openings. In this way, the real capacitance storage area of the capacitor is increased in the vertical direction, so that the area of the capacitor occupying the pixel display region can be reduced. As a result, the aperture ratio of the display region can be increased without deteriorating the predetermined capacitance of the capacitor.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve for explaining the principles of the invention.

FIG. 1 is a schematic top view of a conventional pixel structure.

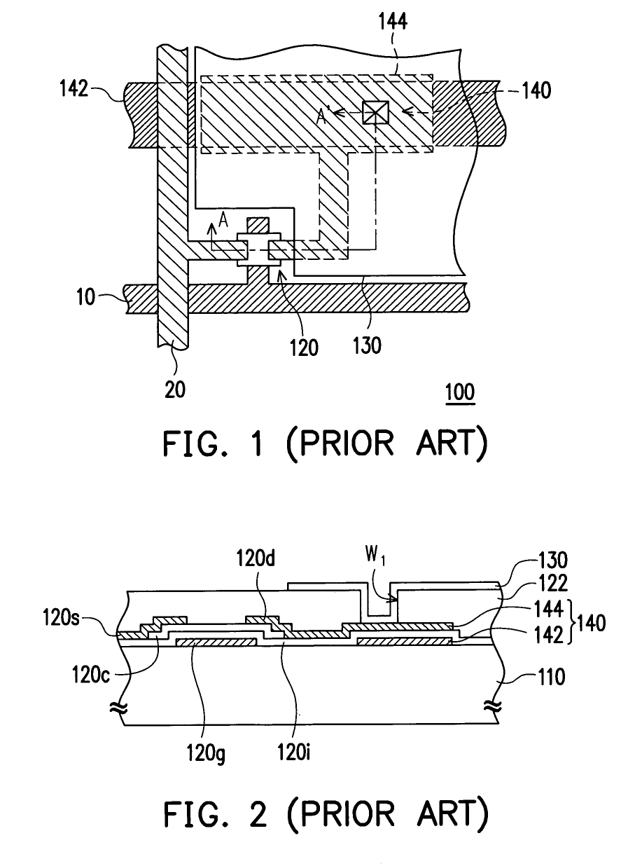

FIG. 2 is a schematic cross-sectional view along plane A-A′ of the conventional pixel structure in FIG. 1.

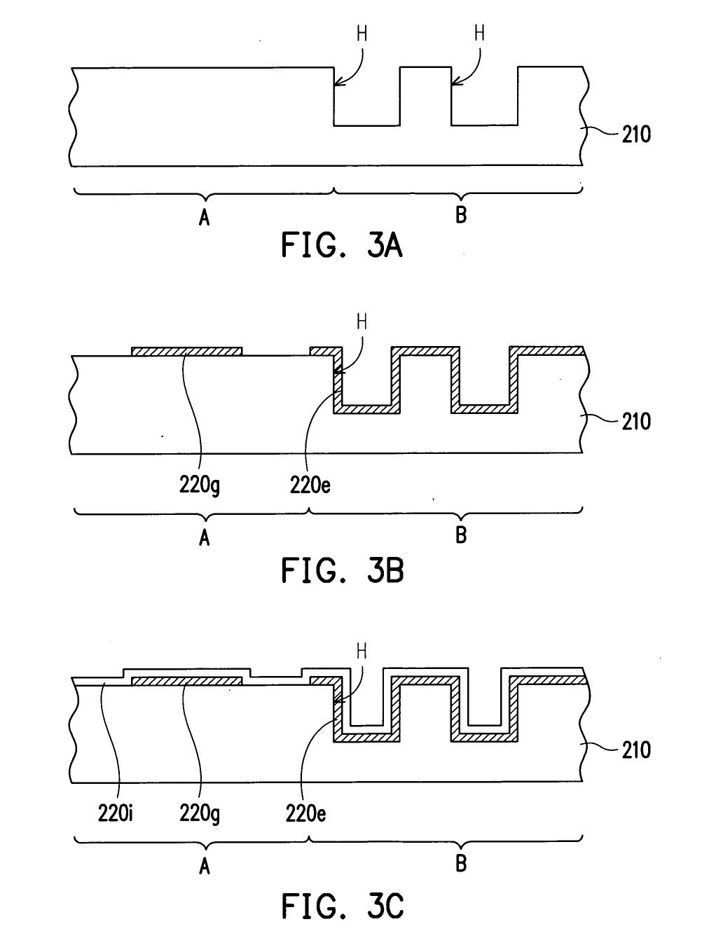

FIGS. 3A˜3H are schematic cross-sectional views showing a fabricating process of a pixel structure in the first embodiment of the present invention.

FIGS. 4A˜4B are schematic cross-sectional views showing a fabricating method for forming openings according to the first embodiment of the present invention.

FIGS. 5A˜5D are schematic cross-sectional views showing another fabricating method for forming openings according to the first embodiment of the present invention.

FIGS. 6A˜6B are schematic cross-sectional views showing a fabricating method for forming a gate and a first electrode layer according to the first embodiment of the present invention.

FIGS. 7A˜7B are schematic cross-sectional views showing a fabricating method for forming a source, a drain and a second electrode layer according to the first embodiment of the present invention.

FIG. 8 is a schematic top view of a pixel structure provided by the first embodiment of the present invention.

FIG. 9 is a schematic cross-sectional view of a pixel structure provided by the second embodiment of the present invention.

FIG. 10 is a schematic top view of a pixel structure in the second embodiment of the present invention.

### DESCRIPTION OF THE EMBODIMENTS

The First Embodiment

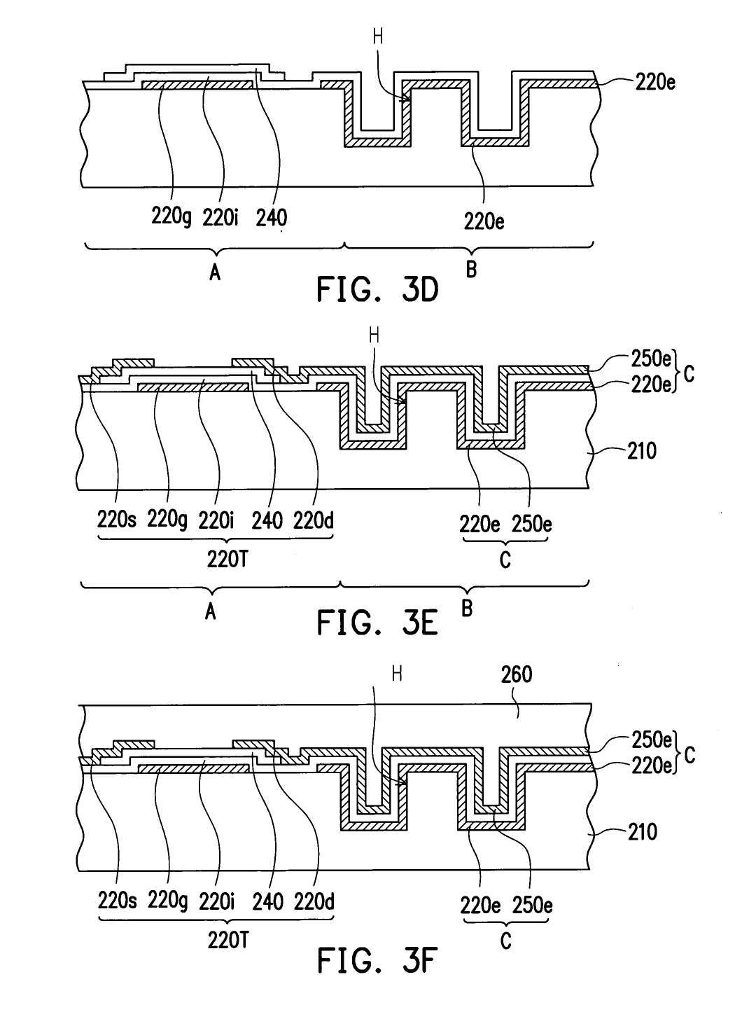

FIGS. 3A˜3H are schematic cross-sectional views showing a fabricating process of a pixel structure in the first embodiment of the present invention. Referring to FIG. 3A, the method for fabricating the pixel structure in the present invention includes the following steps. First, a substrate 210 having an active device region A and a capacitor region B is provided. Next, a plurality of openings H are formed within the capacitor region B of the substrate 210, and the radius of the opening H is, for example, about 0.5˜3 μm, while the depth thereof is, for example, about 5˜10 μm. The space enclosed by the openings H is delicately specified to meet the requirement for forming the capacitor in the opening subsequently (refer to the description in the following). The method for forming the openings is described below through, for example but not limited to, two preferred embodiments.

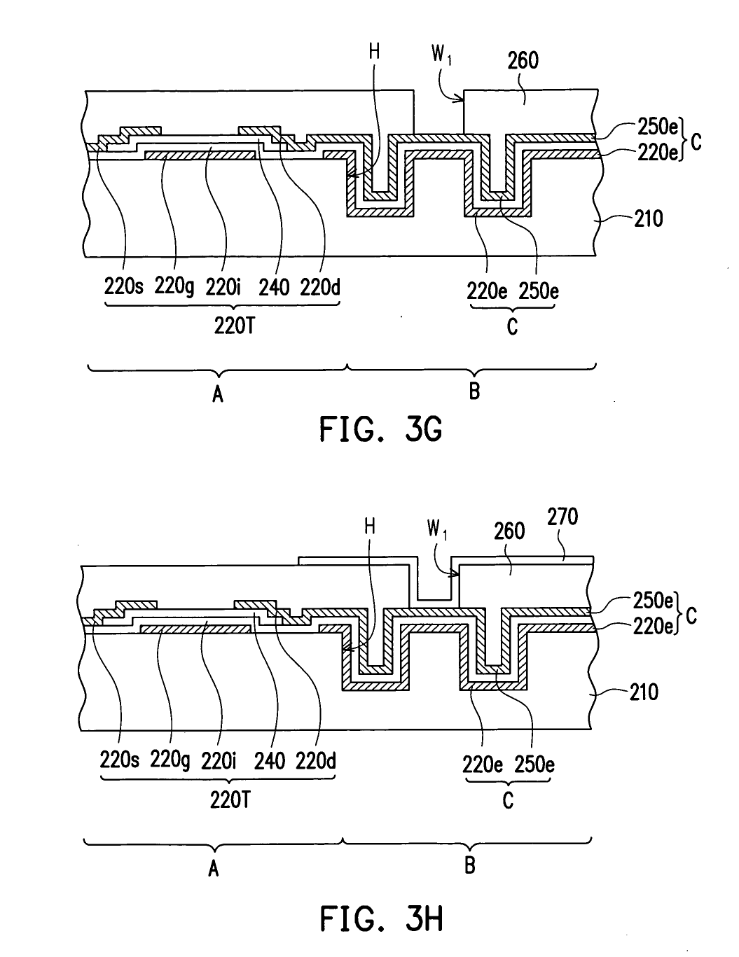

FIGS. 4A˜4B are schematic cross-sectional views showing a fabricating method for forming openings according to the first embodiment of the present invention. The method includes the steps as follows. First, referring to FIG. 4A, a patterned mask layer P made of photoresist is formed on the substrate 210. Next, referring to FIG. 4B, an etching process to the substrate 210 is conducted by using the patterned mask layer P as an etching mask to form the openings H, wherein the etching process applies a dry etching process. Finally, the patterned mask layer P is removed to form a structure as shown in FIG. 3A.

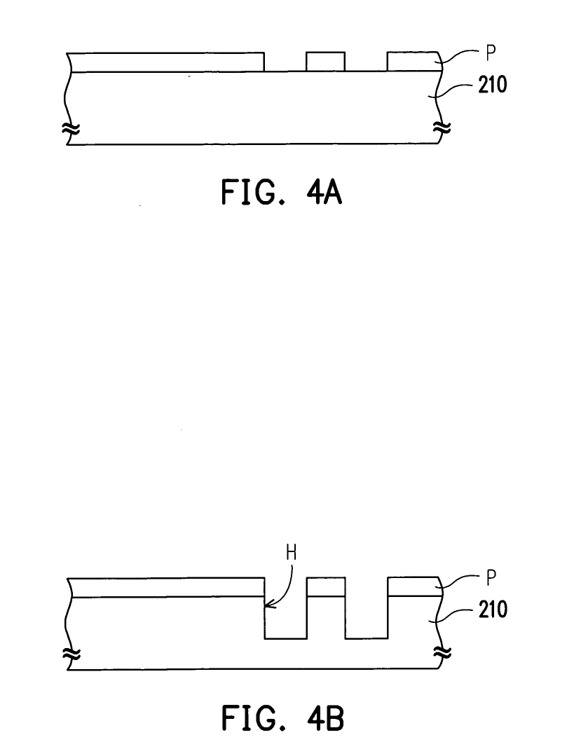

The etching selectivity between the patterned mask layer P and the substrate 210 is determined depending on the depth of the opening H. FIGS. 5A˜5D are schematic cross-sectional views showing another fabricating method for forming openings according to the first embodinent of the present invention. Referring to FIGS. 5A˜5D, the method includes the steps as follows. First, a silicon nitride layer 210a is formed on the substrate 210 (as shown in FIG. 5A). Next, a patterned photoresist layer 210b is formed on the silicon nitride layer 210a (as shown in FIG. 5B). Afterwards, referring to FIG. 5C, an etching process is conducted on the silicon nitride layer 210a by using the patterned photoresist layer 210b as an etching mask to form the patterned mask layer P. In other words, the material of the patterned mask layer P is silicon nitride (SiNx).

Referring to FIG. 5D, an etching process is conducted on the substrate 210 by using the patterned mask layer P as an etching mask to form the openings H, wherein the etching process applies a dry etching process. Since the etching selectivity between the silicon nitride and the substrate 210 is higher than the etching selectivity between the photoresist and the substrate 210, a deeper opening H therefore can be made. Finally, the patterned mask layer P is removed by, for example, a wet etching process to form a structure as shown in FIG. 3A.

After forming the openings H, referring to FIG. 3B, a gate 220g is formed within the active device region A, a first electrode layer 220e is formed within the capacitor region B, and the first electrode layer 220e are formed on the surface of the openings H. In an example, the above-described gate 220g and the first electrode layer 220e are formed at the same time, the material of which is, for example, titanium (Ti), aluminum (Al), titanium nitride (TiN), copper (Cu), chromium (Cr), silver (Ag), molybdenum (Mo) or an alloy/a multi-layer metal structure made up by the mentioned metals.

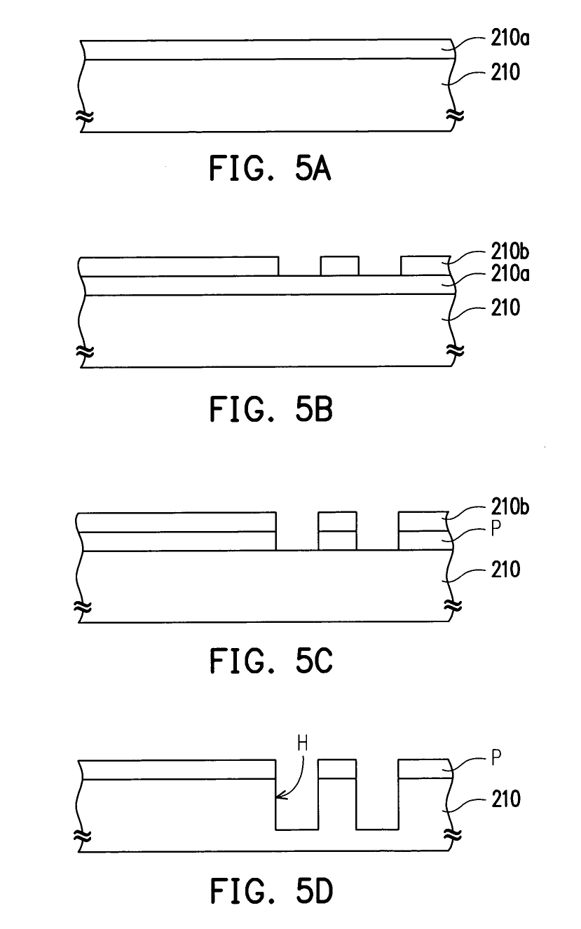

In more detail, the method for forming the gate 220g and the first electrode layer 220e includes the following steps. First, a deposition process is conducted to form a metal layer 220 (as shown in FIG. 6A), wherein the deposition process is selected from a group consisting of an organic metal chemical vapor deposition (organic metal CVD) process, a molecule layer epitaxy process and an atom layer chemical vapor deposition (atom layer CVD) process. Finally, a lithography process and an etching process are conducted for patterning the metal layer (as shown in FIG. 6B), and thus the gate 220g and the first electrode layer 220e are formed (as shown in FIG. 3B).

Further, referring to FIG. 3C, a gate insulation layer 220i is formed on the substrate 210 to cover the gate 220g and the first electrode layer 220e. Furthermore, referring to FIG. 3D, a semiconductor layer 240 is formed on the gate insulation layer 220i over the gate 220g.

Thereafter, referring to FIG. 3E, a source 220s and a drain 220d are formed on the semiconductor layer 240, and a second electrode layer 250e covering the gate insulation layer 220i is formed within the capacitor region B. The above-described first electrode layer 220e, the second electrode layer 250e and the gate insulation layer 220i between two electrode layers 220e and 250e form a capacitor C. Note that the capacitor is formed on the surface of the openings H. Therefore, the area occupied by the capacitor C on the substrate 210 can be reduced without deteriorating the predetermined capacitance so as to increase the aperture ratio of the display region.

In an embodiment, the above-described source 220s, drain 220d and the second electrode layer 250e are formed at the same time, the material of which is, for example, titanium (Ti), aluminum (Al), titanium nitride (TiN), copper (Cu), chromium (Cr), silver (Ag), molybdenum (Mo) or an alloy/a multi-layer metal structure made up by the mentioned metals. In the embodiment, the drain 220d is connected to the second electrode layer 250e and considered as a same film layer. In fact, the drain 220d and the second electrode layer 250e can be alternatively separated, which will be described in the second embodiment hereinafter.

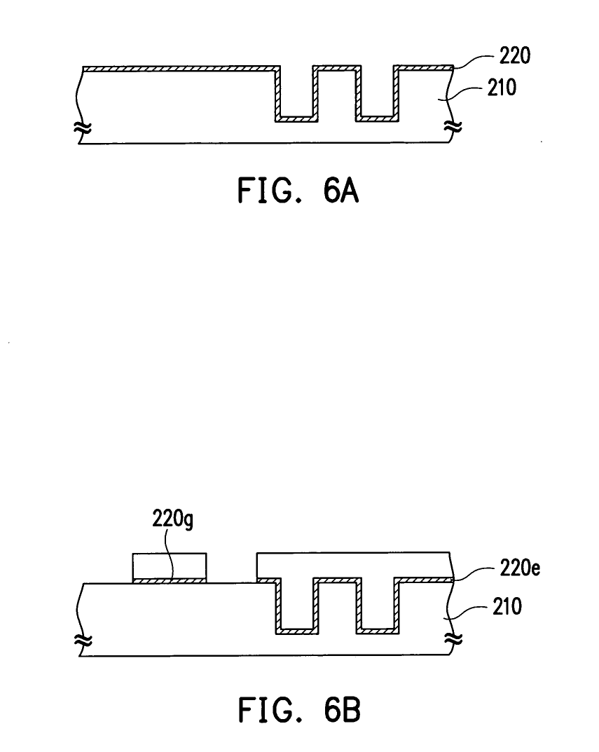

In more detail, the method for forming the source 220s, the drain 220d and the second electrode layer 250e includes the steps as follows. First, a deposition process is conducted to form a metal layer 250 (as shown in FIG. 7A), wherein the deposition process is selected from a group consisting of an organic metal chemical vapor deposition (organic metal CVD) process, a molecule layer epitaxy process and an atom layer chemical vapor deposition (atom layer CVD) process. Then, referring to FIG. 7B, a lithography process and an etching process are conducted for patterning the metal layer 250 so as to form the source 220s, the drain 220d and the second electrode layer 250e. Hereto, a TFT 220T is completed within the active device region A.

After that, referring to FIG. 3F, a protection layer 260 is formed over the substrate and covers the source 220s, the drain 220d and the second electrode layer 250e. Since a plurality of openings H are formed in the substrate 210, for a protection layer 260 to flatly cover the substrate 210, the preferred approach for forming the protection layer 260 is a spin on glass (SOG) process. Subsequently, referring to FIG. 3G, a via hole W1 is formed in the protection layer 260 and exposes the second electrode layer 250e.

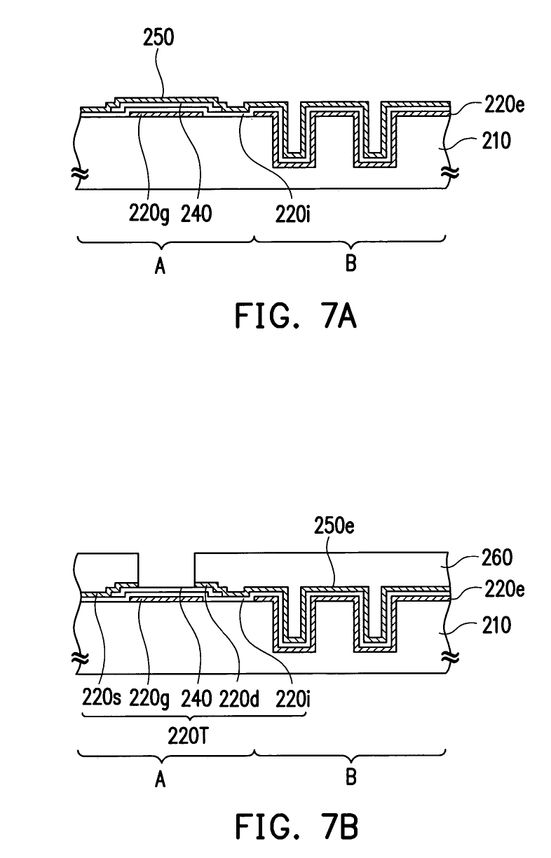

Finally, referring to FIG. 3H, a pixel electrode 270 is formed on the protection layer 260, and the pixel electrode 270 is electrically connected to the second electrode layer 250e and the drain 220d, respectively. The pixel structure 200 of the present invention is completed hereto and the top view thereof is shown in FIG. 8. Referring to FIG. 8 and FIG. 3H, the pixel structure 200 of the present invention includes a substrate 210, a TFT 220T, a capacitor C, a protection layer 260 and a pixel electrode 270. The substrate 210 has an active device region A and a capacitor region B, wherein a plurality of openings H are formed in the capacitor region B. The radius of the opening H is, for example, about 0.5˜3 μg in, while the depth thereof is, for example, about 5˜10% μm.

In addition, the TFT 220T is disposed within the active device region A, while the capacitor C is disposed within the capacitor region B and formed inside the openings H. The protection layer 260 covers the TFT 220T and the capacitor C. The pixel electrode 270 is disposed on the protection layer 260 and electrically connected to the TFT 220T and the capacitor C, respectively. The pixel structure 200 of the present invention is driven by the scanning lines 10 and the data lines 20. According to the present invention, the capacitor C is formed on the surface of the openings H. In this way, the real capacitance storage area of the capacitor C is increased, and thus the area of the capacitor C occupying the substrate 210 can be reduced, so that the aperture ratio of the display region is increased without deteriorating the predetermined capacitance.

The Second Embodiment

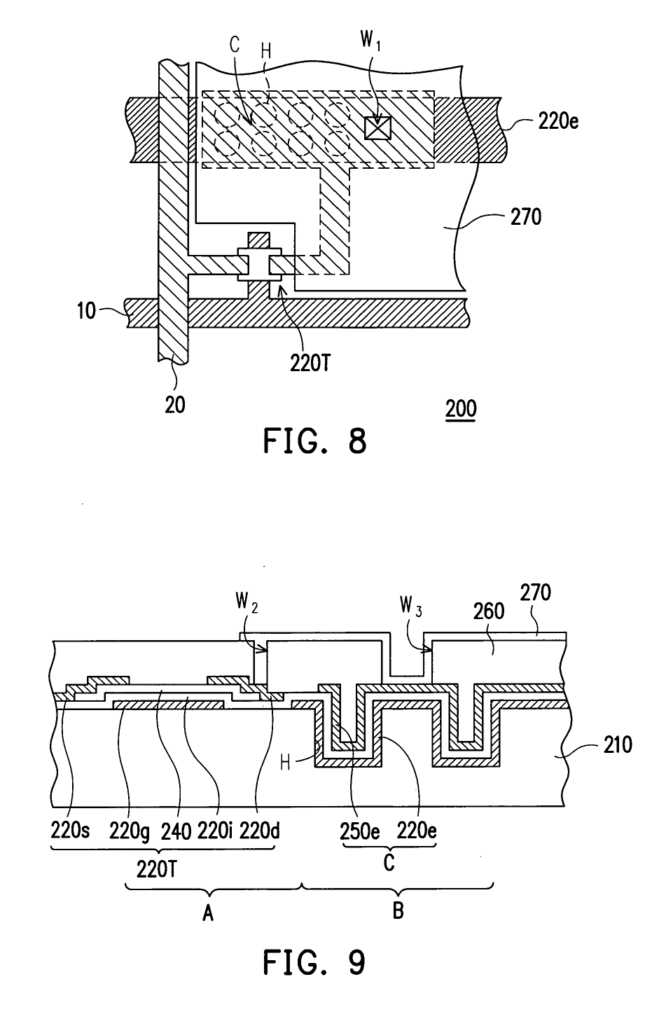

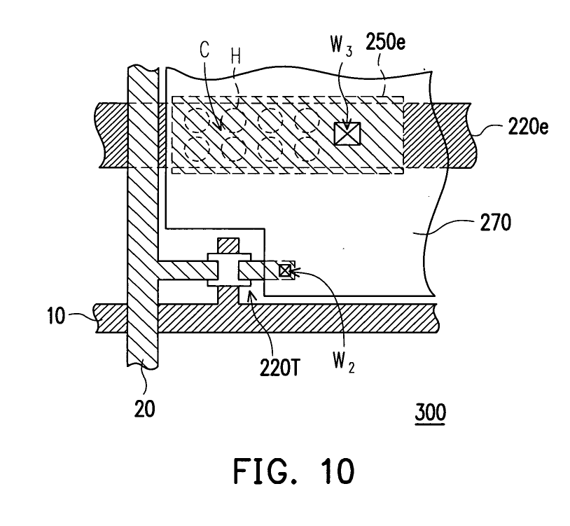

FIG. 9 is a schematic cross-sectional view of a pixel structure in the second embodiment of the present invention. FIG. 10 is a schematic top view of a pixel structure in the second embodiment of the present invention. Referring to FIGS. 9 and 10, it is similar to the first embodiment except that the drain 220d and the second electrode layer 250e in the pixel structure 300 of the embodiment are separated from each other. Therefore, two via holes W2 and W3 need to be formed in the protection level 260 for exposing the drain 220d and the second electrode layer 250e, respectively, and the pixel electrode 270 must be filled into both the via holes W2 and W3 to be electrically connected to the drain 220d and the second electrode layer 250e, respectively.

From the above described, it can be seen that the pixel structure and the method for fabricating the same has at least the following advantages. According to the present invention, the capacitor is formed on the surface of the openings which are previously formed on the substrate, so that the real capacitance storage area of the capacitor is increased. Thus, the area of the capacitor occupying the substrate can be reduced such that the aperture ratio of the display region can be consequently increased without deteriorating the predetermined capacitance.

It will be apparent to those skilled in the art that various modifications and variations can be made to the structure of the present invention without departing from the scope or spirit of the invention. In view of the foregoing, it is intended that the specification and examples to be considered as exemplary only, with a true scope and spirit of the invention being indicated by the following claims and their equivalents.

What is claimed is:

1. A method for fabricating a pixel structure, comprising:
providing a substrate with an active device region and a capacitor region;
forming a plurality of openings within the capacitor region;
forming a gate within the active device region and forming a first electrode layer within the capacitor region, wherein the first electrode layer is formed on the openings;
forming a gate insulation layer on the substrate to cover the gate and the first electrode layer;
forming a semiconductor layer on the gate insulation layer over the gate;
forming a source and a drain on the semiconductor layer and forming a second electrode layer on the gate insulation layer within the capacitor region;
forming a protection layer over the substrate to cover the source, the drain and the second electrode layer; and
forming a pixel electrode on the protection layer, wherein the pixel electrode is electrically connected to the drain and the second electrode layer.

2. The method of claim 1, wherein forming the openings comprises:
forming a patterned mask layer on the substrate;
conducting an etching process to the substrate to form the openings; and
removing the patterned mask layer.

3. The method of claim 2, wherein the material of the patterned mask layer comprises photoresist.

4. The method of claim 2, wherein the material of the patterned mask layer comprises silicon nitride.

5. The method of claim 2, wherein the etching process comprises a dry etching process.

6. The method of claim 4, wherein the process for removing the patterned mask layer comprises a wet etching process.

7. The method of claim 1, wherein the radius of each opening is about 0.5˜3 μm.

8. The method of claim 1, wherein the depth of each opening is about 5˜10 μm.

9. The method of claim 1, wherein forming the protection layer comprises performing a spin on glass (SOG) process.

10. The method of claim 1, wherein prior to forming the pixel electrode on the protection layer, further comprising forming a via hole in the protection layer to expose the drain and the second electrode layer.

11. The method of claim 1, wherein the second electrode layer is connected to the drain.

12. The method of claim 11, wherein prior to forming the pixel electrode on the protection layer, further including forming a via hole in the protection layer to expose the second electrode layer.

13. The method of claim 1, wherein forming the gate and the first electrode layer comprises:
conducting a deposition process to form a metal layer, wherein the deposition process is selected from a group consisting of an organic metal chemical vapor deposition process, a molecule layer epitaxy process and an atom layer chemical vapor deposition process; and
conducting a lithography process and an etching process for patterning the metal layer.

14. The method of claim 1, wherein forming the source, the drain and the second electrode layer comprises:
conducting a deposition process to form a metal layer, wherein the deposition process is selected from a group consisting of an organic metal chemical vapor deposition process, a molecule layer epitaxy process and an atom layer chemical vapor deposition process; and
conducting a lithography process and an etching process for patterning the metal layer.

15. A pixel structure, comprising:
a substrate, having an active device region and a capacitor region, wherein a plurality of openings are formed within the capacitor region;
a thin film transistor (TFT), disposed within the active device region;
a capacitor, disposed within the capacitor region and formed on the openings;
a protection layer, covering the TFT and the capacitor; and
a pixel electrode, disposed on the protection layer and electrically connected to the TFT and the capacitor.

16. The pixel structure as recited in claim 15, wherein the radius of each opening is about 0.5˜3 μm.

17. The pixel structure as recited in claim 15, wherein the depth of each opening is about 5˜10 μm.
